(19) United States
(12) Patent Application Publication
(10) Pub. No.: US 2011/0041767 A1
(43) Pub. Date: Feb. 24, 2011

(54) METAL CAPTURING APPARATUS AND ATOMIC LAYER DEPOSITION APPARATUS HAVING THE SAME

(75) Inventors: Heung-Yeol Na, Yongin-City (KR); Ki-Yong Lee, Yongin-City (KR); Jin-Wook Seo, Yongin-City (KR); Min-Jae Jeong, Yongin-City (KR); Jong-Won Hong, Yongin-City (KR); Eu-Gene Kang, Yongin-City (KR); Seok-Rak Chang, Yongin-City (KR); Yun-Mo Chung, Yongin-City (KR); Tae-Hoon Yang, Yongin-City (KR); Byoung-Keon Park, Yongin-City (KR); Dong-Hyun Lee, Yongin-City (KR); Kil-Won Lee, Yongin-City (KR); Jong-Ryuk Park, Yongin-City (KR); Bo-Kyung Choi, Yongin-City (KR); Jae-Wan Jung, Yongin-City (KR); Byung-Soo So, Yongin-City (KR); Won-Bong Baek, Yongin-City (KR); Ivan Maidanchuk, Yongin-City (KR)

Correspondence Address: STEIN MCEWEN, LLP, 1400 EYE STREET, NW, SUITE 300, WASHINGTON, DC, 20005, US

(73) Assignee: Samsung Mobile Display Co., Ltd., Yongin-City (KR)

(21) Appl. No.: 12/713,995

(22) Filed: Feb. 26, 2010

(30) Foreign Application Priority Data
Aug. 21, 2009 (KR) 10-2009-0077605

(51) Int. Cl. C23C 16/00; B01D 49/00; B01D 8/00

(52) U.S. Cl. 118/724; 62/532; 62/123

(57) ABSTRACT

A metal capturing apparatus and an atomic layer deposition apparatus, which are capable of discharging an exhaust gas from a process chamber, in which a metal atomic layer is deposited on a substrate using a reaction gas containing a metal catalyst, without a scrubber, and easily reusing the metal catalyst contained in the exhaust gas. The metal capturing apparatus includes a capturing chamber having a capturing space, a capturing plate disposed at one side of the capturing chamber and partially inserted into the capturing chamber, a refrigerant source feeding a refrigerant cooling the capturing plate, and an attachment unit attaching the capturing plate to the capturing chamber. The atomic layer deposition apparatus includes a process chamber, a vacuum pump connected to an exhaust port of the process chamber, and a metal capturing apparatus disposed between the process chamber and the vacuum pump.

### CROSS-REFERENCE TO RELATED APPLICATIONS

This application claims the benefit of Korean Patent Application No. 10-2009-0077605, filed Aug. 21, 2009, the disclosure of which is hereby incorporated herein by reference in its entirety.

### BACKGROUND

1. Field

Aspects of the present invention relate to a metal capturing apparatus and an atomic layer deposition apparatus having the same, and more particularly, to a metal capturing apparatus and an atomic layer deposition apparatus having the same, capable of discharging an exhaust gas from a process chamber, in which a metal atomic layer is deposited on a substrate using a reaction gas containing a metal catalyst, without a scrubber, and easily reusing the metal catalyst contained in the exhaust gas.

2. Description of the Related Art

Flat panel display devices are generally preferred over cathode ray tube display devices due to characteristics such as light weight, thinness, and so on, and typical examples thereof include liquid crystal displays (LCDs) and organic light emitting diode (OLED) display devices. In comparison with the LCDs, the OLED display devices have excellent brightness and viewing angle characteristics and require no backlight, so that the OLED display devices can be realized as ultra thin displays.

The OLED display devices are classified into two types, a passive matrix type and an active matrix type, according to a driving method. An active matrix OLED display device includes a circuit using a thin film transistor (TFT).

The TFT generally includes a semiconductor layer having a source region, a drain region, a channel region, gate electrodes, source electrodes, and drain electrodes. The semiconductor layer may be formed of polycrystalline silicon (poly-Si) or amorphous silicon (a-Si). The poly-Si has a higher electron mobility than the a-Si. Thus, the poly-Si is generally used at present.

Among the methods of crystallizing the a-Si into the poly-Si, one is a crystallizing method using a metal. The crystallizing method using the metal can crystallize the a-Si at a relatively low temperature in a short time by depositing a metal catalyst on a substrate using a process such as a sputtering process of depositing a metal layer on a substrate by applying plasma to a metal target, or an atomic layer deposition (ALD) process of forming an atomic layer of the metal catalyst on the substrate using a chemical method based on a reaction gas containing the metal catalyst, and crystallizing the a-Si using the metal catalyst as a seed.

However, an ALD apparatus forms an atomic layer of a metal catalyst on the substrate using a chemical method based on a reaction gas containing the metal catalyst such as nickel, and then exhausts the metal catalyst remaining in a process chamber using a purge gas such as nitrogen gas. Since the metal catalyst such as nickel is a carcinogenic substance, the exhaust gas discharged from the process chamber must be purified and discharged using, for instance, a scrubber. Moreover, the metal catalyst contained in the exhaust gas discharged from the process chamber is completely discarded, so that it is difficult to avoid wasting the metal catalyst used in the ALD process.

### SUMMARY

Aspects of the present invention provide a metal capturing apparatus and an atomic layer deposition apparatus having the same, capable of discharging an exhaust gas from a process chamber to the outside without a scrubber, and easily reusing a metal catalyst contained in the exhaust gas.

According to aspects of the present invention, a metal capturing apparatus includes a capturing chamber having a capturing space, a capturing plate disposed at one side of the capturing chamber and partially inserted into the capturing chamber; a refrigerant source feeding a refrigerant cooling the capturing plate, and an attachment unit attaching the capturing plate to the capturing chamber.

According to another aspect of the present invention, an atomic layer deposition apparatus includes a process chamber, a vacuum pump connected with an exhaust port of the process chamber, and a metal capturing apparatus disposed between the process chamber and the vacuum pump. Here, the metal capturing apparatus includes a capturing chamber having a capturing space, a capturing plate partially inserted into the capturing chamber, a refrigerant source feeding a refrigerant cooling the capturing plate, and an attachment unit attaching the capturing plate to the capturing chamber.

Thus, the atomic layer deposition apparatus according to the other exemplary embodiment of the present invention disposes the metal capturing apparatus, which includes the capturing chamber providing a capturing space and the capturing plate partially inserted into the capturing chamber, at the exhaust port of the process chamber, thereby allowing the exhaust gas to be discharged from the process chamber to the outside without a scrubber and thus reducing costs required to install the scrubber. Further, the atomic layer deposition apparatus causes the capturing plate of the metal capturing apparatus to be selectively attached to or detached from the capturing chamber, thereby allowing the metal catalyst captured from the exhaust gas by the capturing plate to be easily reused and thus reducing costs required for an atomic layer deposition process.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 schematically illustrates an atomic layer deposition apparatus according to an exemplary embodiment of the present invention; and

FIG. 2 schematically illustrates a metal capturing apparatus in the atomic layer deposition apparatus according to an exemplary embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. In the drawings, the thicknesses of layers and regions may not be illustrated at scale and may be exaggerated for clarity. The embodiments are described below in order to explain the present invention by referring to the figures.

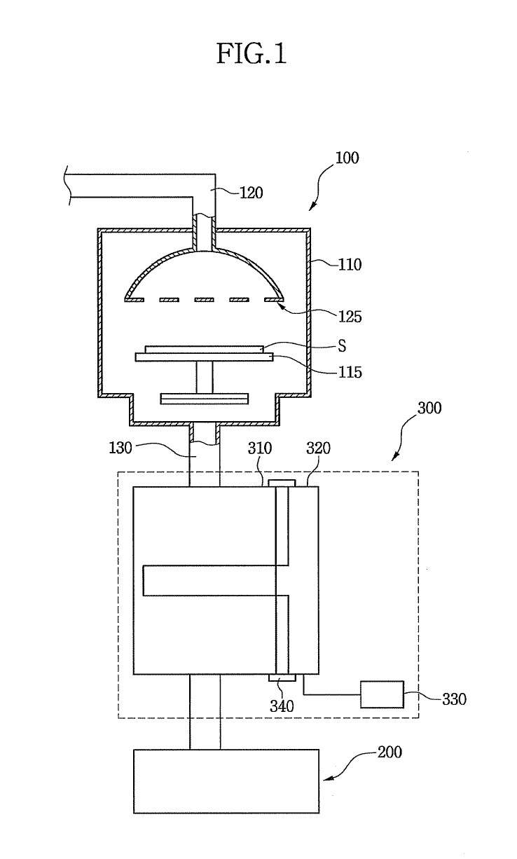

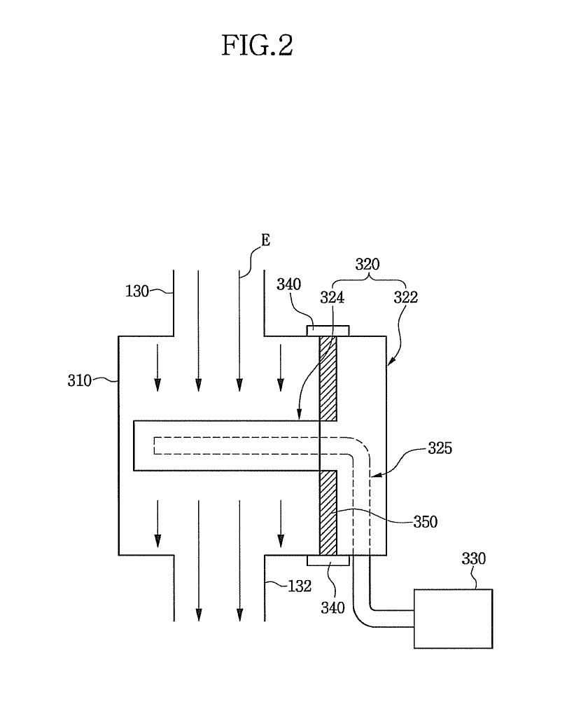

FIG. 1 schematically illustrates an atomic layer deposition apparatus according to an exemplary embodiment of the present invention, and FIG. 2 schematically illustrates a metal capturing apparatus in the atomic layer deposition apparatus according to an exemplary embodiment of the present invention.

Referring to FIGS. 1 and 2, the an atomic layer deposition apparatus according to an exemplary embodiment of the present invention includes a process chamber 100, a vacuum pump 200 connected with an exhaust port of the process chamber 100, and a metal capturing apparatus 300 disposed between the process chamber 200 and the vacuum pump 200 and capturing a metal catalyst from an exhaust gas discharged from the process chamber 100.

The process chamber 100 includes a chamber body 110, an inflow pipe 120 introducing a reaction gas containing the metal catalyst or a purge gas such as nitrogen gas after an atomic layer deposition (ALD) process is completed into the chamber body 110, a shower head 125 uniformly spraying the reaction gas or the purge gas introduced through the inflow pipe 120 on a substrate S, a support chuck 115 supporting the substrate S, and an exhaust pipe 130 discharging the metal catalyst remaining in the chamber body 110.

Here, the support chuck 115 of the process chamber 100 may include a temperature controller (not shown), which maintains the substrate S at a predetermined temperature in order to smoothly perform the ALD process. The metal catalyst may include nickel used to form a polycrystalline silicon layer on the substrate using a crystallizing method such as super grain silicon (SGS) crystallization, metal induced crystallization (MIC), metal induced lateral crystallization (MILC), or the like.

The vacuum pump 200 keeps the process chamber 100 under vacuum, and discharges the purge gas introduced into the process chamber 100 to the outside after the ALD process is completed. The vacuum pump 200 may be a low-temperature pump in order to prevent the exhaust gas discharged from the process chamber 100 from reacting with each other and prevent the layer formed on the substrate from being damaged,

The metal capturing apparatus 300 is disposed between the process chamber 100 and the vacuum pump 200, and captures the metal catalyst contained in the exhaust gas discharged through the exhaust pipe 130 of the process chamber 100. The metal capturing apparatus 300 includes a capturing chamber 310, a capturing plate 320 partially inserted into the capturing chamber 310, a refrigerant source 330 feeding a refrigerant cooling the capturing plate 320, and an attachment unit 340 selectively attaching or detaching the capturing plate 320 to or from the capturing chamber 310.

The capturing plate 320 includes a body 322 attached onto one side of the capturing chamber 310, and at least one capturing finger 324 protruding from the body 322 and inserted in the capturing chamber 310. Here, the body 322 and the capturing finger 324 are provided therein with a refrigerant pipe 325, through which a refrigerant fed from the refrigerant source 330 can flow. The refrigerant, which is fed to the body 322 and the capturing finger 324 through the refrigerant pipe 325 from the refrigerant source 330, may include helium (He) gas, because the metal capturing apparatus 300 must be cooled to a very low temperature in order to capture the metal catalyst such as nickel.

The capturing finger 324, which is inserted into the capturing chamber 310, is cooled to a very low temperature by the refrigerant fed from the refrigerant source 330, and captures the metal catalyst from the exhaust gas passing through the capturing chamber 310. In order to improve capturing efficiency, a plurality of capturing fingers 324 may be stacked in the same direction as a flow of the exhaust gas E passing through the capturing chamber 310.

The attachment unit 340 selectively attaches or detaches the capturing plate 320 to or from the capturing chamber 310. In detail, the attachment unit 340 is configured to attach the capturing plate 320 to the capturing chamber 310 while the ALD process is carried out in the process chamber 100, and while a purging process of discharging the exhaust gas from the process chamber 100 is carried out. In contrast, the attachment unit 340 is configured to detach the capturing plate 320 from the capturing chamber 310 after the purging process of the process chamber 100 is completed. Thereby, the metal catalyst captured on the capturing finger 324 of the capturing plate 320 can be easily reused.

In the exemplary embodiment of the present invention, the attachment unit 340 has been described as a separate means separated from the capturing chamber 310 and the capturing plate 320. However, the attachment unit 340 may be located at the body 322 of the capturing plate 320, and selectively attach the body 322 to the capturing chamber 310.

The metal capturing apparatus 300 may further include a sealing member 350 interposed between the capturing chamber 310 and the capturing plate 320 such that the exhaust gas passing through the capturing chamber 310 does not leak out between the capturing chamber 310 and the capturing plate 320. When the attachment unit 340 is located at the body 322, the attachment unit 340 may be located at an edge of the body 322 to easily locate the sealing member 350 between the capturing chamber 310 and the capturing plate 320.

Consequently, an atomic layer deposition apparatus, according to an exemplary embodiment of the present invention, has a metal capturing apparatus, which includes a capturing chamber 310, providing a capturing space and a capturing plate 320 partially inserted into the capturing chamber 310, at an exhaust port of a process chamber 100, thereby allowing the exhaust gas to be discharged from the process chamber 100 to the outside without a scrubber. Further, the atomic layer deposition apparatus causes the capturing plate 320 of the metal capturing apparatus to be selectively attached to or detached from the capturing chamber 310, thereby allowing the metal catalyst captured from the exhaust gas by the capturing plate 320 to be easily reused.

Accordingly, it is possible to reduce costs involved in installing the scrubber, and depositing the atomic layer.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A metal capturing apparatus comprising:
a capturing chamber having a capturing space;
a capturing plate disposed at one side of the capturing chamber and partially inserted into the capturing chamber;
a refrigerant source feeding a refrigerant cooling the capturing plate; and
an attachment unit attaching the capturing plate to the capturing chamber.

2. The metal capturing apparatus according to claim 1, wherein the capturing plate comprises:
a body attached to the capturing chamber; and
at least one capturing finger inserted into the capturing chamber.

3. The metal capturing apparatus according to claim 2, wherein the capturing plate comprises a plurality of capturing fingers inserted into the capturing chamber and stacked in the same direction as a flow of an exhaust gas passing through the capturing chamber.

4. The metal capturing apparatus according to claim 2, further comprising a sealing member interposed between the capturing chamber and the body.

5. The metal capturing apparatus according to claim 2, wherein the attachment unit is located at an edge of the body of the capturing plate.

6. The metal capturing apparatus according to claim 1, wherein the capturing plate comprises a refrigerant pipe therein through which the refrigerant flows.

7. The metal capturing apparatus according to claim 1, wherein the refrigerant comprises helium (He) gas.

8. A atomic layer deposition (ALD) apparatus comprising:
a process chamber performing an ALD process;
a vacuum pump connected to an exhaust port of the process chamber; and
a metal capturing apparatus disposed between the process chamber and the vacuum pump,
wherein the metal capturing apparatus comprises:
a capturing chamber having a capturing space;
a capturing plate partially inserted into the capturing chamber;
a refrigerant source feeding a refrigerant cooling the capturing plate; and
an attachment unit attaching the capturing plate to the capturing chamber.

9. The atomic layer deposition apparatus according to claim 8, wherein the capturing plate comprises:
a body attached to the capturing chamber; and
at least one capturing finger inserted into the capturing chamber.

10. The atomic layer deposition apparatus according to claim 9, wherein the capturing plate comprises a plurality of capturing fingers inserted into the capturing chamber and stacked in the same direction as a flow of an exhaust gas passing through the capturing chamber.

11. The atomic layer deposition apparatus according to claim 9, further comprising a sealing member interposed between the capturing chamber and the body of the capturing plate.

12. The atomic layer deposition apparatus according to claim 9, wherein the attachment unit is located at an edge of the body of the capturing plate.

13. The atomic layer deposition apparatus according to claim 8, wherein the capturing plate comprises a refrigerant pipe therein through which the refrigerant flows.

14. The atomic layer deposition apparatus according to claim 8, wherein the refrigerant comprises helium (He) gas.

15. The atomic layer deposition apparatus according to claim 8, wherein the process chamber comprises:
a chamber body;
an inflow pipe introducing a reaction gas or a purge gas into the chamber body;
a shower head uniformly spraying the reaction gas or the purge gas introduced through the inflow pipe on a substrate;
a support chuck supporting the substrate; and
an exhaust pipe exhausting a metal catalyst remaining in the chamber body.

16. The atomic layer deposition apparatus according to claim 15, wherein the support chuck comprises a temperature controller maintaining the temperature of the supported substrate.

17. The metal capturing apparatus according to claim 1, wherein the attachment unit selectively detaches the capturing plate from the capturing chamber.

18. The atomic layer deposition apparatus according to claim 8, wherein the attachment unit selectively detaches the capturing plate from the capturing chamber.

19. The metal capturing apparatus according to claim 6, wherein the refrigerant pipe is disposed in the body of the at least one capturing finger of the capturing plate and is attached to the refrigerant source.

20. The atomic layer deposition apparatus according to claim 13, wherein the refrigerant pipe is disposed in the body of the at least one capturing finger of the capturing plate and is attached to the refrigerant source.

21. A capturing plate of a metal capturing apparatus, the capturing plate comprising:
a capturing finger disposed in a direction traversing the flow of an exhaust gas having metal; and
a body attached to the capturing finger.

22. The capturing plate of claim 21, further comprising a refrigerant pipe disposed in the body and the capturing finger.

23. The capturing plate of claim 21, wherein the refrigerant pipe is connected to a refrigerant source and feeds a refrigerant to the capturing plate.

24. The capturing plate of claim 22, wherein the refrigerant includes helium (He) gas.

25. The capturing plate of claim 21, wherein an attachment unit attaches the body of the capturing plate to an apparatus through which the exhaust gas flows.

26. The capturing plate of claim 25, wherein the body unit comprises the attachment unit.

27. A method of capturing metal in an atomic layer deposition (ALD) operation, the method comprising:
disposing a capturing finger in a direction traversing a flow of exhaust gas of the ALD operation;
cooling the capturing finger; and
passing the exhaust gas of the ALD operation over the capturing finger in order to capture metal in the exhaust gas.

28. The method of claim 27, wherein a plurality of capturing fingers are disposed in the direction traversing the flow of the exhaust gas of the ALD operation.

29. The method of claim 27, further comprising:
removing the capturing finger from the flow of the exhaust gas of the ALD operation; and
collecting the captured metal from the capturing finger.

30. The method of claim 27, further comprising discharging the exhaust gas from a chamber in which the ALD operation is performed.

31. The method of claim 27, wherein the cooling the capturing finger comprises passing a refrigerant through the capturing finger.

32. The method of claim 31, wherein the refrigerant comprises helium (He) gas.
